(19) United States
(12) Patent Application Publication
(10) Pub. No.: US 2020/0133066 A1
(43) Pub. Date: Apr. 30, 2020

(54) HEAT DISSIPATION DEVICE OF BACKLIGHT MODULE, BACKLIGHT MODULE AND DISPLAY DEVICE

(71) Applicant: HUIZHOU CHINA STAR OPTOELECTRONICS TECHNOLOGY CO., LTD., Huizhou Guangdong (CN)

(72) Inventors: Dehua LI, Huizhou Guangdong (CN); Gang YU, Huizhou Guangdong (CN)

(21) Appl. No.: 15/752,539

(22) PCT Filed: Jan. 18, 2018
(86) PCT No.: PCT/CN2018/073279

§ 371 Date: Feb. 13, 2018

(30) Foreign Application Priority Data
Dec. 27, 2017 (CN) 201711450587.6

(51) Int. Cl. G02F 1/1335; H05K 7/20

(52) U.S. Cl. CPC G02F 1/133603; G02F 2001/133628; H05K 7/20972

(57) ABSTRACT

The present application discloses a heat dissipation device of a backlight module, a backlight module and a display device. The heat dissipation device includes a heat sink for mounting a light source, wherein a side of the heat sink is provided with a heat sink wind slot, two ends of the heat sink wind slot are respectively formed with a gas inlet and a gas outlet; and a constant fan, wherein an opening of the constant fan is corresponding to the gas inlet of the heat sink wind slot. The heat dissipation device of the backlight module of the invention adopts the constant fan and introduces the airflow into the heat sink wind slot to remove the heat, so as to achieve the purpose of active heat dissipation.

### RELATED APPLICATIONS

The present application is a National Phase of International Application Number PCT/CN2018/073279, filed Jan. 18, 2018, and claims the priority of China Application 201711450587.6, filed Dec. 27, 2017.

### FIELD OF THE DISCLOSURE

The disclosure relates to a display technical field, and more particularly to a heat dissipation device of a backlight module, a backlight module and a display device.

### BACKGROUND

The liquid crystal display device generally includes a backlight module and a liquid crystal display panel stacking arranged, the liquid crystal display panel itself does not emit light, and the backlight module is required to provide a backlight for display. Light-emitting diode, LED as a typical point light source device, is often used as a key component applied to the backlight module. One of the more commonly used is to use a plurality of light-emitting diodes as a point light source array disposed on a surface of a printed circuit board, PCB to form a light bar. The plurality of light-emitting diodes emit light under the driving of the printed circuit board, and further to form a bar-shaped line light source, and then the light emitting direction is changed by a light guide plate, LGP of the backlight module to obtain a uniform surface light source.

With the development of the liquid crystal display, the pursuit of image quality is getting higher and higher. Regardless of upgrade in resolution, brightness or color gamut, it means the improvement of the light source power consumption, leading to a greatly increase in heat dissipation requirement. In the past, the heat dissipation performance required by the light source was relatively low, only passive radiating heat dissipation (capacity density<0.1 W/MM) is needed. However, with the needs of the improved image quality, the passive heat dissipation has been unable to meet the demand.

### SUMMARY

An object of the present invention is to provide a heat dissipation device of a backlight module, a backlight module and a display device, so as to overcome the insufficiency in the conventional technology.

To achieve the above object, the present invention provides the following technical solutions:

The embodiment of the present application discloses a heat dissipation device for a backlight module, including:

A heat sink for mounting a light source, wherein a side of the heat sink is provided with a heat sink wind slot, two ends of the heat sink wind slot are respectively formed with a gas inlet and a gas outlet; and

A constant fan, wherein an outlet of the constant fan is corresponding to the gas inlet of the heat sink wind slot.

Wherein the heat sink includes a plurality of fins arranged in an array, a sealing cover is covered on an outer side of the fins, and the heat sink wind slots are enclosed between the sealing cover and the fins.

Wherein the gas outlet is disposed on the sealing cover.

Wherein baffles are distributed in an array inside the gas outlet.

Wherein the fins are integrally formed on the heat sink.

Wherein the sealing cover includes a panel and three side plates formed from bending from three sides of the panel to the same side, the three side plates block a side of the fin, the sealing cover exposes a side of the heat sink wind slot to form the gas inlet, and the gas outlet is disposed on the panel.

Correspondingly, the present application also discloses a backlight module including:

The heat dissipation device;

A light source mounted on the heat sink;

Preferably, in the above backlight module, one of the heat sink wind slot extending in a vertical direction is enclosed between adjacent fins, and the gas inlet is formed at a top of the heat sink wind slot.

Correspondingly, the present application also discloses a display device including:

A liquid crystal display panel;

A backlight module for providing backlight to perform display for the liquid crystal display panel;

A cover body covering an outside of the backlight module, wherein the cover body is provided with a heat dissipation hole corresponding to the gas outlet.

Compared with the conventional technology, the present invention has the advantages that: the heat dissipation device of the backlight module of the invention adopts the constant fan and introduces the airflow into the heat sink wind slot to remove the heat, so as to achieve the purpose of active heat dissipation.

### BRIEF DESCRIPTION OF THE DRAWINGS

To describe the technical solutions in the embodiments of the present application or in the conventional technology more clearly, the following briefly introduces the accompanying drawings required for describing the embodiments or the prior art. Apparently, the accompanying drawings in the following description merely show some embodiments described in this application. For those skilled in the art, other drawings may be obtained based on these drawings without any creative work.

FIG. 1 is a perspective view of a heat dissipation device of a backlight module according to a specific embodiment of the present invention;

FIG. 2 is an exploded perspective view of the heat dissipation device of the backlight module according to the embodiment of the present invention;

FIG. 3 shows an enlarged schematic diagram of A in FIG. 2;

FIG. 4 shows a schematic view of the structure of the heat sink in an embodiment of the present invention;

FIG. 5 is an assembled view of a display device (without a cover body) according to a specific embodiment of the present invention; and

FIG. 6 is an assembled view of a display device (with the cover body) according to a specific embodiment of the present invention.

### DETAILED DESCRIPTION OF PREFERRED EMBODIMENTS

The technical solution of the present invention will be dearly and completely described below with reference to the accompanying drawings. Apparently, the described embodiments are merely some but not all embodiments of the present invention. All other embodiments obtained by a person of ordinary skill in the art based on the embodiments of the present invention without creative efforts shall fall within the protection scope of the present invention.

In the description of the present invention, it is noted that the terms center, upper, lower, left, right, vertical, horizontal, inner, outer, etc. The indicated orientation or positional relationship is based on the orientation or positional relationship shown in the drawings, merely for the convenience of describing the invention and for simplifying the description, rather than indicating or implying that the indicated device or element must have a particular orientation, in a particular orientation Structure and operation, and thus cannot be understood as a limitation of the present invention. In addition, the terms “first”, “second” and “third” are used for descriptive purposes only and are not to be construed as indicating or implying relative importance.

In the description of the present invention, it should be noted that the terms “mounted,” “linked,” and “connected” should be broadly understood unless the context dearly indicates otherwise. For example, the terms fixed connection and removable connected, or integrally connected; it may be a mechanical connection or an electrical connection; it may be directly connected or indirectly connected through an intermediary medium and may be an internal communication between the two components. For those skilled in the art, the specific meanings of the above terms in the present invention may be understood based on specific cases.

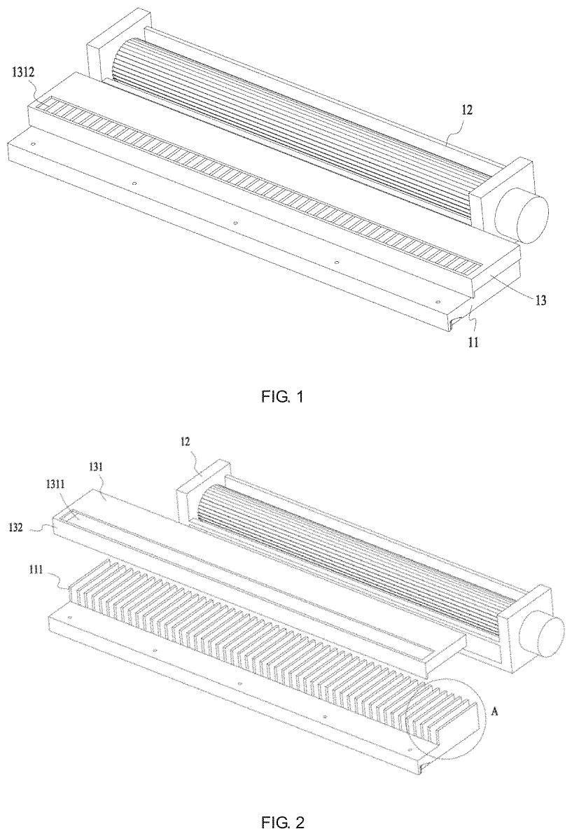

Combining as shown in FIG. 1 and FIG. 2, in one embodiment, the heat dissipation device 10 includes a heat sink 11, a constant fan 12, and a sealing cover 13.

The heat sink 11 is used to mount a light source. The other side of the heat sink 11 opposite to the light source protrudes of distributed fins 111 in an array.

In a preferred embodiment, the fin 111 is integrally formed on the heat sink 11.

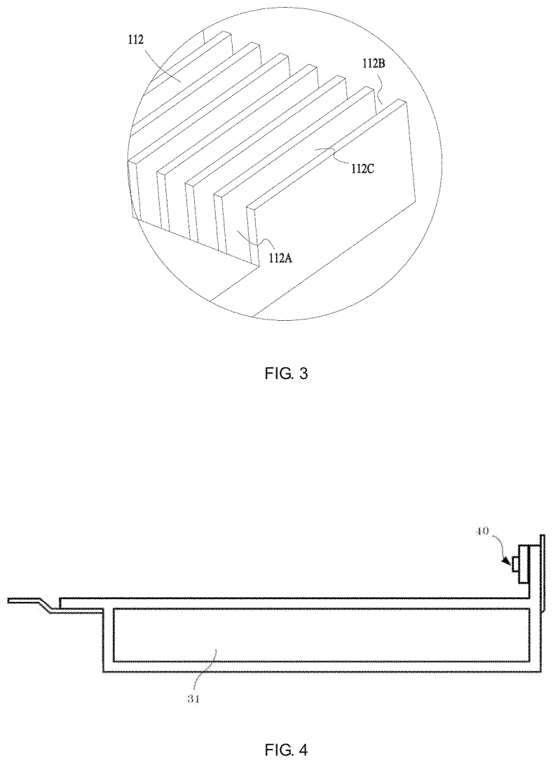

Combining as shown in FIG. 3, the fins 111 are heat sink sheets arranged in parallel and spaced apart, heat sink wind slots 112 are formed between the adjacent fins 111. Two ends 112A, 112B of the heat sink wind slot 112 and a top end 112C are opened.

In a preferred embodiment, the heat sink 11 is entirely made of aluminum material or electrolytic zinc-plated galvanized steel sheet material to achieve rapid heat transfer.

The sealing cover 13 is a cover body, including a panel 131 and three side plates 132 a panel and three side plates formed from bending from three sides of the panel 131 to the same side. Correspondingly, the panel 131 correspondingly covers openings of the top ends 112C of the heat sink wind slots 112, one of the side plates correspondingly covers end openings 112A of the heat sink wind slots 112.

In this embodiment, the sealing cover 13 does not cover the end openings 112B of the heat sink wind slots 112, and serves as a gas inlet of the heat sink wind slots 112.

The panel 131 is provided with an opening 1311 communicating with the plurality of heat sink wind slots 112 respectively, and the opening 1311 serves as gas inlets of the heat sink wind slots 112.

Further, baffles 1312 are array distributed in the opening 1311.

In order to ensure that the gas flows through the entire heat sink wind slots 112, the opening 1311 is disposed at an end away from the gas inlet 112B.

The gas outlet of the constant fan 12 is corresponding to the end openings 112B of the heat sink wind slots 112, for sending cold air into the heat sink wind slots 112, and then brings out the heat inside the heat sink wind slots 112 from the opening 1311.

Due to the limited cross width of the micro constant fan 12, a plurality of constant fans can be arranged side by side in the horizontal direction in the present application.

In other embodiments, the gas outlet of the heat sink wind slots 112 may be disposed on the side plate, for example, the panel is a continuous flat plate, the blocking of the end opening 112A of the heat sink wind slot 112 is canceled, and the end opening 112A serves as a gas outlet of the heat sink wind slot 112. However, the technical solution has some disadvantages. For example, the heat dissipation area below is small, resulting in poor airflow, and covering the cover body outside the backlight module, the heat dissipation hole is usually disposed on the housing opposite to the display panel to increase the heat dissipation surface, this causes the hot air of the end opening 112A to come out after going through a long path to dissipate the heat, and thus has low heat dissipation efficiency, therefore, this embodiment is not preferable in the present application.

As a preferred embodiment of the present application, the gas outlet on the panel 131 is disposed opposite to the heat dissipation hole 31 on the cover body 30, to reduce the heat dissipation path, and increase the heat dissipation surface. The structure is compact and has high heat dissipation efficiency.

Further, the sealing cover 13 and the heat sink 11 are detachably connected by a screw or a buckle.

Combining as shown in FIG. 4, in another embodiment, the heat sink wind slot 31 may also be integrally formed on one side of the heat sink. It can be a rectangular cross-section airflow channel, four boundaries are closed, both ends are opened, one end is disposed opposite to the constant fan, the other end is as a gas outlet.

It is easy to think that one end of the airflow channel can also be closed, and then a hole can be formed in the side wall of the airflow channel as a gas outlet.

In this embodiment, one heat sink wind slot 31 may be provided, and a heat sink sheet may be further added in the heat sink wind slot.

In one embodiment, the present application further discloses a backlight module, including the heat dissipation device 10 shown in FIGS. 1 to 4, and also included is a light source 40 disposed on the heat sink.

The light source preferably adopts a plurality of light-emitting diodes as a point light source array and is arranged on the surface of a printed circuit board, PCB to form a light bar. The plurality of light-emitting diodes emit light under the driving of the printed circuit board, to form a bar-shaped line light source, and then the light emit direction is changed by the light guide plate, LGP of the backlight module to obtain a uniform surface light source.

In this embodiment, the heat sink wind slot extends in a vertical direction, and the end opening 112B is formed at the top of the heat sink wind slot.

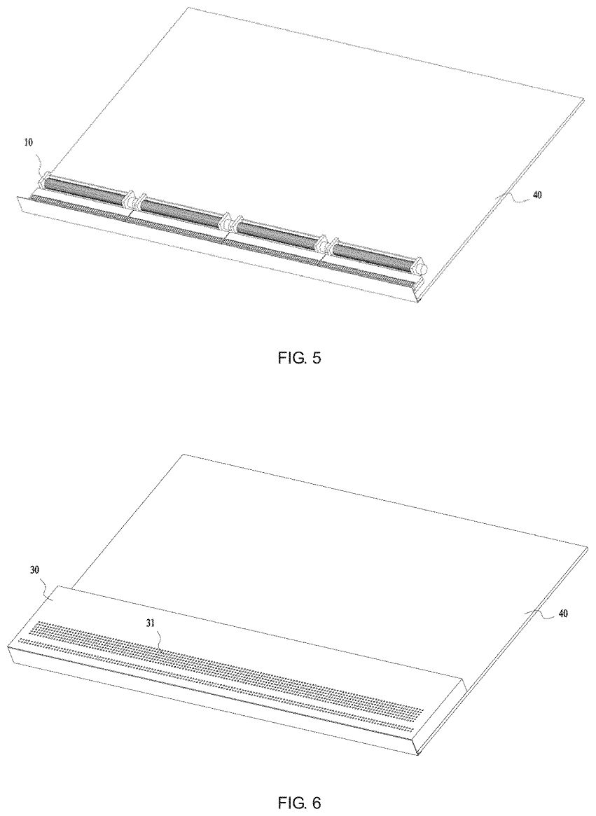

Combining as shown in FIG. 5 and FIG. 6, in one embodiment, a display device is also disclosed. The display device includes a liquid crystal display panel 50, a backlight module mounted on the back of the liquid crystal display panel 50, and a cover body 30 covering the outside of the backlight module. Wherein the cover body 30 is provided with a heat dissipation hole 31 corresponding to the opening 1311.

In summary, the working principle of this application is: the light source is fixed on the heat sink, the heat dissipated by the light source is transmitted to the heat sink fins through the heat sink, the constant fan draws the airflow from the fan surface, and then emerges from the radial direction and enters the heat sink wind slot of the heat sink, the airflow absorbs heat in the flowing process in the heat sink wind slot; adding a sealing cover, to ensure that the airflow is flow between the fins; disposing baffle in the tail portion of the sealing cover, so that the flow with heat is flow to the outside according to a prescribed direction; when forming to a whole machine, ventilation holes are designed at the constant fan and the position of the cover corresponding to the air outlet to ensure a good circulation of hot and cold air.

Finally, it should be noted that the foregoing embodiments are merely intended for describing the technical solutions of the present invention, but not for limiting the present invention. Although the present invention is described in detail with reference to the foregoing embodiments, it should be understood by those ordinary skilled in the art that: The technical solutions described in the foregoing embodiments may still be modified or equivalent replacements may be made to part or all of the technical features without departing from the spirit of the technical solutions in the embodiments of the present invention range.

What is claimed is:

1. A heat dissipation device of a backlight module, comprising:
a heat sink for mounting a light source, wherein a side of the heat sink is provided with a heat sink wind slot, two ends of the heat sink wind slot are respectively formed with a gas inlet and a gas outlet; and
a constant fan, wherein an outlet of the constant fan is corresponding to the gas inlet of the heat sink wind slot.

2. The heat dissipation device of the backlight module according to claim 1, wherein the heat sink comprises a plurality of fins arranged in an array, a sealing cover is covered on an outer side of the fins, and the heat sink wind slots are enclosed between the sealing cover and the fins.

3. The heat dissipation device of the backlight module according to claim 2, wherein the gas outlet is disposed on the sealing cover.

4. The heat dissipation device of the backlight module according to claim 3, wherein baffles are distributed in an array inside the gas outlet.

5. The heat dissipation device of the backlight module according to claim 2, wherein the fins are integrally formed on the heat sink.

6. The heat dissipation device of the backlight module according to claim 2, wherein the sealing cover comprises a panel and three side plates formed from bending from three sides of the panel to the same side, the three side plates block a side of the fin, the sealing cover exposes a side of the heat sink wind slot to form the gas inlet, and the gas outlet is disposed on the panel.

7. A backlight module comprising a light source and a heat dissipation device, wherein the heat dissipation device comprising:
a heat sink for mounting a light source, wherein a side of the heat sink is provided with a heat sink wind slot, two ends of the heat sink wind slot are respectively formed with a gas inlet and a gas outlet;
a constant fan, wherein an outlet of the constant fan is corresponding to the gas inlet of the heat sink wind slot; and
wherein the light source is mounted on the heat sink.

8. The backlight module according to claim 7, wherein the heat sink comprises a plurality of fins arranged in an array, a sealing cover is covered on an outer side of the fins, and the heat sink wind slots are enclosed between the sealing cover and the fins.

9. The backlight module according to claim 8, wherein the gas outlet is disposed on the sealing cover.

10. The backlight module according to claim 9, wherein baffles are distributed in an array inside the gas outlet.

11. The backlight module according to claim 8, wherein the fins are integrally formed on the heat sink.

12. The backlight module according to claim 8, wherein the sealing cover comprises a panel and three side plates formed from bending from three sides of the panel to the same side, the three side plates block a side of the fin, the sealing cover exposes a side of the heat sink wind slot to form the gas inlet, and the gas outlet is disposed on the panel.

13. The backlight module according to claim 7, wherein one of the heat sink wind slot extending in a vertical direction is enclosed between adjacent fins, and the gas inlet is formed at a top of the heat sink wind slot.

14. A display device comprising:
a liquid crystal display panel;
a backlight module for providing backlight to perform display for the liquid crystal display panel, the backlight module comprising a light source and a heat dissipation device, wherein the heat dissipation device comprising a constant fan and a heat sink for mounting a light source, wherein a side of the heat sink is provided with a heat sink wind slot, two ends of the heat sink wind slot are respectively formed with a gas inlet and a gas outlet, an outlet of the constant fan is corresponding to the gas inlet of the heat sink wind slot and the light source is mounted on the heat sink;
a cover body covering an outside of the backlight module, wherein the cover body is provided with a heat dissipation hole corresponding to the gas outlet.

15. The display device according to claim 14, wherein the heat sink comprises a plurality of fins arranged in an array, a sealing cover is covered on an outer side of the fins, and the heat sink wind slots are enclosed between the sealing cover and the fins.

16. The display device according to claim 15, wherein the gas outlet is disposed on the sealing cover.

17. The display device according to claim 16, wherein baffles are distributed in an array inside the gas outlet.

18. The display device according to claim 15, wherein the fins are integrally formed on the heat sink.

19. The display device according to claim 15, wherein the sealing cover comprises a panel and three side plates formed from bending from three sides of the panel to the same side, the three side plates block a side of the fin, the sealing cover exposes a side of the heat sink wind slot to form the gas inlet, and the gas outlet is disposed on the panel.

20. The display device according to claim 14, wherein one of the heat sink wind slot extending in a vertical direction is enclosed between adjacent fins, and the gas inlet is formed at a top of the heat sink wind slot.
